(19) United States
(12) Patent Application Publication
(10) Pub. No.: US 2012/0229993 A1
(43) Pub. Date: Sep. 13, 2012

(54) ANTISTATIC CIRCUIT BOARD AND ELECTRICAL DEVICE USING SAME

(75) Inventors: WEI-CHIEH CHOU, Tu-Cheng (TW); YING-TSO LAI, Tu-Cheng (TW); YUNG-CHIEH CHEN, Tu-Cheng (TW)

(73) Assignee: HON HAI PRECISION INDUSTRY CO., LTD., Tu-Cheng (TW)

(21) Appl. No.: 13/108,997

(22) Filed: May 17, 2011

(30) Foreign Application Priority Data
Mar. 10, 2011 (TW) 100108031

(51) Int. Cl. H05K 7/14; H05K 1/02; H05F 3/00

(52) U.S. Cl. 361/752; 174/250

(57) ABSTRACT

An exemplary antistatic circuit board includes a first outer layer, a second outer layer, a first ground layer, and a second ground layer. The first ground layer and the second ground layer are positioned between the first outer layer and the second outer layer. The first ground layer is adjacent to the first outer layer and the second ground layer is adjacent to the second outer layer. The antistatic circuit board defines two position holes each penetrating through the first ground layer and the second ground layer. Two circuit grounds are wired on the first ground layer and the second ground layer, respectively. The second ground layer further includes a chassis ground. Each of the position holes also penetrates through the chassis ground.

### BACKGROUND

1. Technical Field

The present disclosure relates to circuit boards, and particularly, to an antistatic circuit board and an electrical device using the same.

2. Description of Related Art

In a typical circuit board, electrical connectors are positioned on the circuit board for connecting peripherals. During the process of hot plugging the peripherals, other electrical elements positioned on the circuit board may be damaged by static charges generated by friction between the peripherals and the connectors. In order to eliminate the static charges, a number of extra antistatic elements are assembled on the circuit board. However, providing the antistatic elements is somewhat inconvenient and costly.

Therefore, it is desirable to provide a circuit board which can overcome the limitations described.

### BRIEF DESCRIPTION OF THE DRAWINGS

FIG. 1 is an isometric, exploded, schematic view of an electrical device in accordance with an exemplary embodiment.

FIG. 2 is an enlarged, cross-sectional view of part of an antistatic circuit board of the electrical device of FIG. 1.

FIG. 3 is a cross-sectional view of part of a second ground layer of the antistatic circuit board of FIG. 2, corresponding to line III-III thereof.

FIG. 4 is a signal waveform graph showing a trace of the antistatic circuit board of FIG. 2 and a trace of a traditional circuit board.

### DETAILED DESCRIPTION

Embodiments of the disclosure will now be described in detail, with reference to the accompanying drawings.

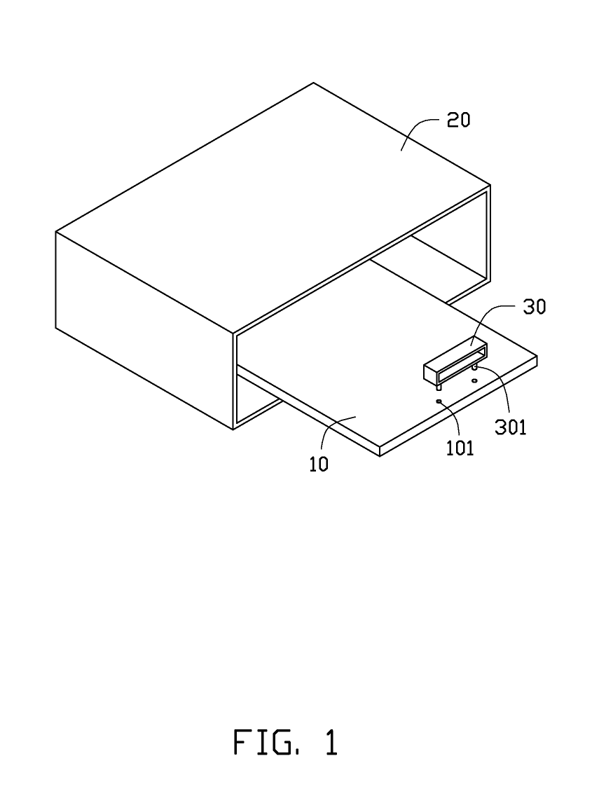

Referring to FIG. 1, an electrical device 100, according to an exemplary embodiment, includes an antistatic circuit board 10, a case 20, and a connector 30. The antistatic circuit board 10 is received in the case 20, and defines at least one position hole 101 thereon. The at least one position hole 101 is adjacent to an edge of the antistatic circuit board 10. At least one position pole 301 extends from a bottom side of the connector 30. The connector 30 is positioned on the antistatic circuit board 10 by the at least one position pole 301 being received in the at least one position hole 101. The connector 30 protrudes from one side of the case 20. In this embodiment, the connector 30 is a Universal Serial Bus (USB) connector, and there are two position poles 301 and two position holes 101.

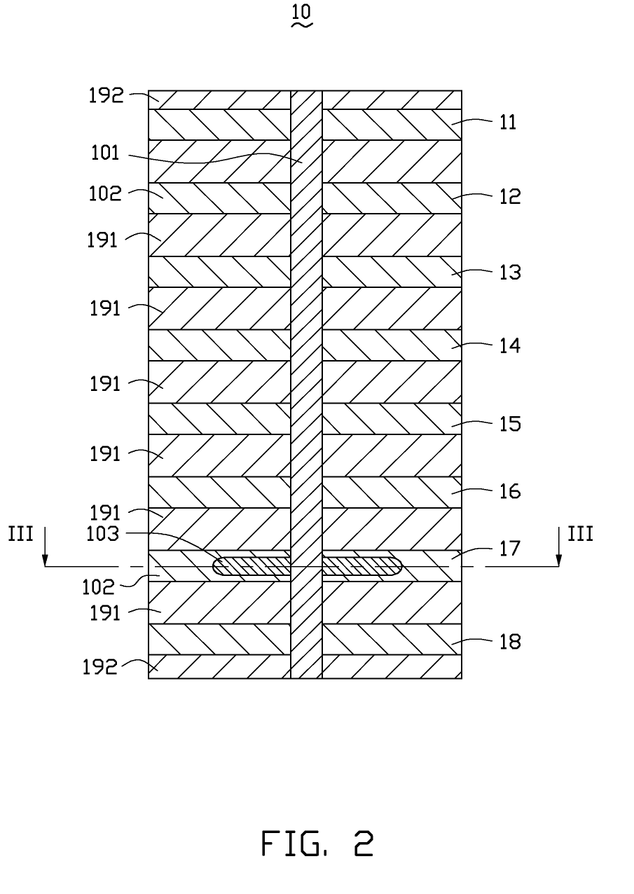

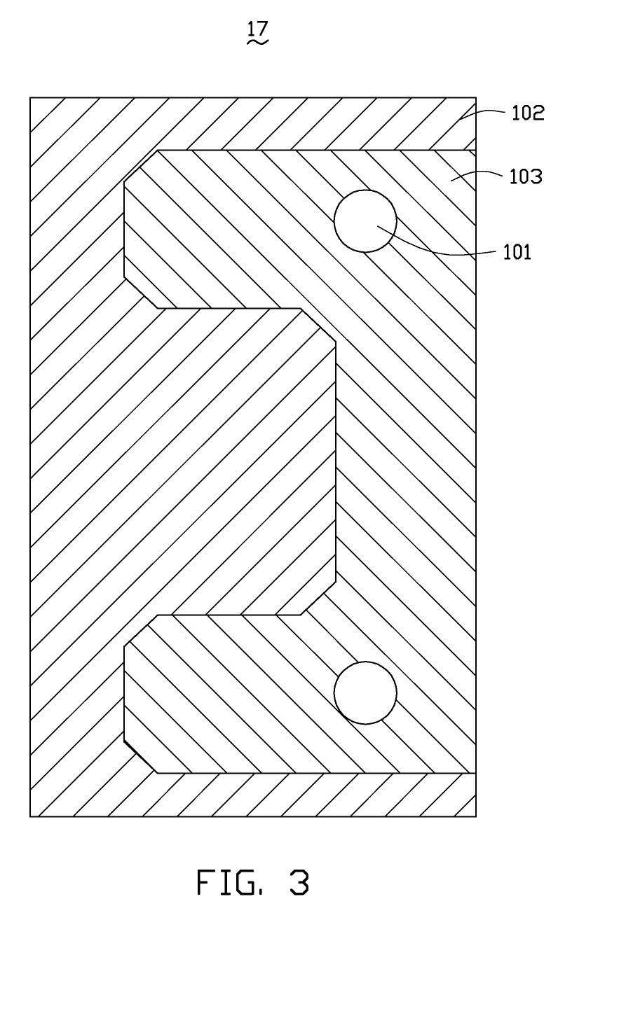

Referring also to FIGS. 2-3, the antistatic circuit board 10 includes, in order from a top side aligned with the connector 30 to an opposite bottom side, a first outer layer 11, a first ground layer 12, a first signal layer 13, a first power layer 14, a second power layer 15, a second signal layer 16, a second ground layer 17, and a second outer layer 18. The antistatic circuit board 10 further includes a number of insulating layers 191 respectively sandwiched between each two adjacent of the above-described layers, such as between the first outer layer 11 and the first ground layer 12, and between the first power layer 14 and the second power layer 15.

The first outer layer 11 and the second outer layer 18 are configured for bearing a number of electrical elements, such as capacitors and resistors. Two protective layers 192 are covered on an outer surface of the first outer layer 11 and an outer surface of the second outer layer 18, respectively. The first ground layer 12 is a main signal reference layer, and the second ground layer 17 is a secondary signal reference layer. Both the first ground layer 12 and the second ground layer 17 are connected to the case 20. The first signal layer 13 is used for wiring main signal circuits, and the second signal layer 16 is used for wiring secondary signal circuits. The quality requirement of signals flowing in the first signal layer 13 may be higher than that of the second signal layer 16. The first ground layer 12 is a signal reference layer of the first signal layer 13, and the second ground layer 17 is a signal reference layer of the second signal layer 16. The first power layer 14 and the second power layer 15 are used for wiring power circuits.

The first ground layer 12 and the second ground layer 17 are each used for wiring a circuit ground 102 thereon. The circuit ground 102 of the first ground layer 12 is a ground point of the first signal layer 13, and the circuit ground 102 of the second ground layer 17 is another ground point of the second signal layer 16. The second ground layer 17 further wires a chassis ground 103 thereon. The chassis ground 103 is adjacent to an edge of the antistatic circuit board 10, and the circuit ground 102 of the second ground layer 17 partially surrounds the chassis ground 103. In the illustrated embodiment, the circuit ground 102 of the second ground layer 17 surrounds one half of the chassis ground 103. The chassis ground 103 is a metal layer with good electrical conductivity. The position holes 101 penetrate all the way through the circuit board 10, including through the chassis ground 103 of the second ground layer 17.

During the process of a USB device being hot plugged into the connector 30, any static charge(s) generated as a result of friction is transmitted to the antistatic circuit board 10 by the position poles 301. The static charges are transmitted to the second ground layer 17 because of the chassis ground 103 being positioned in the second ground layer 17. The static charges are not transmitted to the first ground layer 12. Therefore, the static charges do not disturb signals in the first signal layer 13.

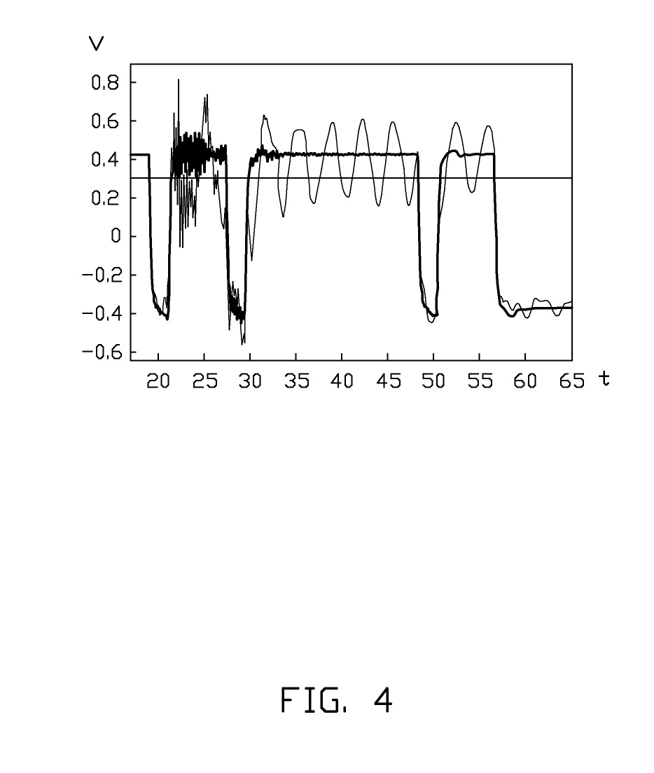

Referring to FIG. 4, the thick line represents a waveform of a signal transmitted in the first signal layer 13, and the thin line represents a waveform of a signal in a traditional circuit board. It can be noted that the static disturbance in the traditional circuit board is clearly greater than the static disturbance in the antistatic circuit board 10.

In this specification, particular embodiments are shown and described by way of illustration only. The principles and the features of the present disclosure may be employed in various and numerous embodiments thereof without departing from the scope of the disclosure. The above-described embodiments illustrate the scope of the disclosure but do not restrict the scope of the disclosure.

What is claimed is:

1. An antistatic circuit board comprising:
a first outer layer, a second outer layer, a first ground layer, and a second ground layer; the first ground layer and the second ground layer positioned between the first outer layer and the second outer layer, the first ground layer adjacent to the first outer layer and the second ground layer adjacent to the second outer layer;
the antistatic circuit board defining at least one position hole penetrating through both the first ground layer and the second ground layer; and the first ground layer and the second ground layer respectively wiring a circuit ground thereon;
the second ground layer further wiring a chassis ground thereon, and the at least one position hole also penetrating through the chassis ground.

2. The antistatic circuit board of claim 1, further comprising, in order from the first ground layer to the second ground layer, a first signal layer, a first power layer, a second layer, and a second signal layer.

3. The antistatic circuit board of claim 2, wherein the first signal layer is used for wiring main signal circuits and the second signal layer is used for wiring secondary signal circuits.

4. The antistatic circuit board of claim 3, wherein the first ground layer is a main signal reference layer of the first signal layer and the second ground layer is a secondary signal reference layer of the second signal layer.

5. The antistatic circuit board of claim 4, wherein the circuit ground of the first ground layer is a ground point of the first signal layer and the circuit ground of the second ground layer is a ground point of the second signal layer.

6. The antistatic circuit board of claim 1, wherein the circuit ground of the second ground layer surrounds one half of the chassis ground.

7. An electrical device comprising:
a case;
an antistatic circuit board receiving in the case and comprising:
a first outer layer, a second outer layer, a first ground layer, and a second ground layer; the first ground layer and the second ground layer positioned between the first outer layer and the second outer layer, the first ground layer adjacent to the first outer layer and the second ground layer adjacent to the second outer layer;
the antistatic circuit board defining at least one position hole penetrating through both the first ground layer and the second ground layer; and the first ground layer and the second ground layer respectively wiring a circuit ground thereon;
the second ground layer further wiring a chassis ground thereon, and the at least one position hole also penetrating through the chassis ground; and
a connector comprising at least one position pole extending from a side thereof, the connector positioned on the antistatic circuit board by the at least one position pole being received in the at least one position hole, and the connector protruding from one side of the case.

8. The electrical device of claim 7, wherein the antistatic circuit board further comprises, in order from the first ground layer to the second ground layer, a first signal layer, a first power layer, a second layer, and a second signal layer.

9. The electrical device of claim 8, wherein the first signal layer used for wiring main signal circuits and the second signal layer used for wiring secondary signal circuits.

10. The electrical device of claim 9, wherein the first ground layer is a main signal reference layer of the first signal layer and the second ground layer is a secondary signal reference layer of the second signal layer.

11. The electrical device of claim 10, wherein the circuit ground of the first ground layer is a ground point of the first signal layer and the circuit ground of the second ground layer is a ground point of the second signal layer.

12. The electrical device of claim 7, wherein the circuit ground of the second ground layer surrounds one half of the chassis ground.

13. An electrical device comprising:
an antistatic circuit board comprising:
a first outer layer, a second outer layer, a first ground layer, and a second ground layer; the first ground layer and the second ground layer positioned between the first outer layer and the second outer layer, the first ground layer adjacent to the first outer layer and the second ground layer adjacent to the second outer layer;
the antistatic circuit board defining at least one position hole penetrating through both the first ground layer and the second ground layer; and the first ground layer and the second ground layer respectively wiring a circuit ground thereon;
the second ground layer further wiring a chassis ground thereon, and the at least one position hole also penetrating through the chassis ground; and
a connector comprising at least one position pole extending from a side thereof, the connector positioned on the antistatic circuit board by the at least one position pole being received in the at least one position hole.

14. The electrical device of claim 13, wherein the antistatic circuit board further comprises, in order from the first ground layer to the second ground layer, a first signal layer, a first power layer, a second layer, and a second signal layer.

15. The electrical device of claim 14, wherein the first signal layer used for wiring main signal circuits and the second signal layer used for wiring secondary signal circuits.

16. The electrical device of claim 15, wherein the first ground layer is a main signal reference layer of the first signal layer and the second ground layer is a secondary signal reference layer of the second signal layer.

17. The electrical device of claim 16, wherein the circuit ground of the first ground layer is a ground point of the first signal layer and the circuit ground of the second ground layer is a ground point of the second signal layer.

18. The electrical device of claim 13, wherein the circuit ground of the second ground layer surrounds one half of the chassis ground.
